(19) United States
(12) Patent Application Publication
(10) Pub. No.: US 2025/0280562 A1
(43) Pub. Date: Sep. 4, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chang-Yih Chen, Tainan City (TW); Kuo-Hsing Lee, Hsinchu County (TW); Chun-Hsien Lin, Tainan City (TW); Chih-Yi Wang, Tainan City (TW)

(73) Assignee: UNITED MICROELECTRONICS CORP., Hsin-Chu City (TW)

(21) Appl. No.: 18/631,070

(22) Filed: Apr. 10, 2024

(30) Foreign Application Priority Data
Mar. 4, 2024 (TW) 113107653

(51) Int. Cl. H01L 29/78; H01L 21/768; H01L 29/66

(52) U.S. Cl. CPC H10D 30/62; H01L 21/7682; H10D 30/024

(57) ABSTRACT

A semiconductor device includes a metal gate on a substrate, a spacer adjacent to the metal gate, an interlayer dielectric (ILD) layer around the metal gate, a first air gap adjacent to one side of the metal gate and between the spacer and the metal gate, and a second air gap adjacent to another side of the metal gate and between the spacer and the metal gate. Preferably, the metal gate includes a high-k dielectric layer on the substrate, a work function metal (WFM) layer on the high-k dielectric layer, and a low resistance metal layer on the WFM layer.

### BACKGROUND OF THE INVENTION

### 1. Field of the Invention

The invention relates to a semiconductor device and fabrication method thereof, and more particularly to a semiconductor device having air gap between high-k dielectric layer and low resistance metal layer and fabrication method thereof.

### 2. Description of the Prior Art

As technology advances, augmented reality (AR) and virtual reality (VR) applications also progresses rapidly and in a foreseen future, AR and VR applications will likely be applicable to our daily lives including various applications in the fields of education, logistics, medicine, and military.

Currently, AR and VR applications are commonly implemented by head-mounted displays. The head-mounted displays in most circumstances connect the display driver integrated circuits (DDICs) including high-voltage (HV) devices, medium-voltage (MV) devices, and/or low-voltage (LV) devices to a display module through extremely long wires or metal interconnections. This design is typically applied to larger scale products that not only consumes a great amount of space but also increases the difficulty for mounting the device. Hence, how to improve the current process for producing a display device suitable for both AR and VR environments has become an important task in this field.

### SUMMARY OF THE INVENTION

According to an embodiment of the present invention, a method for fabricating semiconductor device includes the steps of first forming a metal gate on a substrate and an interlayer dielectric (ILD) layer around the metal gate, removing part of the metal gate to form a first recess, and then forming a buffer layer on the metal gate to seal the first recess for forming a first air gap.

According to another aspect of the present invention, a semiconductor device includes a metal gate on a substrate, a spacer adjacent to the metal gate, an interlayer dielectric (ILD) layer around the metal gate, a first air gap adjacent to one side of the metal gate and between the spacer and the metal gate, and a second air gap adjacent to another side of the metal gate and between the spacer and the metal gate. Preferably, the metal gate includes a high-k dielectric layer on the substrate, a work function metal (WFM) layer on the high-k dielectric layer, and a low resistance metal layer on the WFM layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

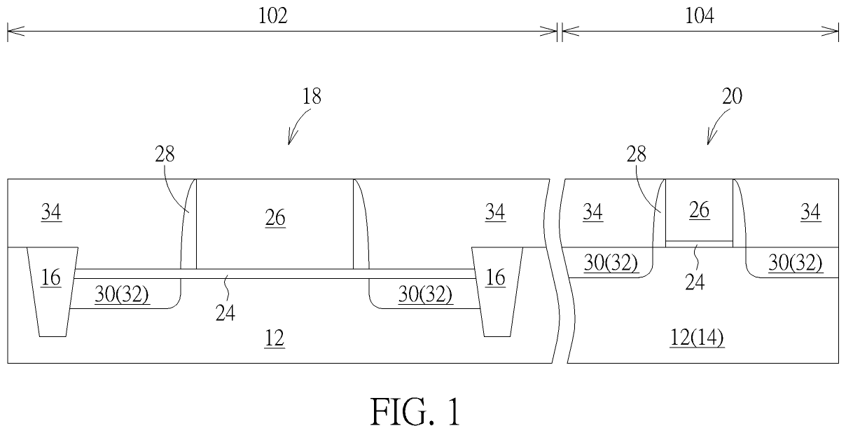

Referring to FIGS. 1-5, FIGS. 1-5 illustrate a method for fabricating a semiconductor device according to an embodiment of the present invention. As shown in FIG. 1, a substrate 12, such as a silicon substrate or silicon-on-insulator (SOI) substrate is first provided and a planar region 102 and a non-planar region 104 are defined on the substrate 12, in which the planar region 12 could be used to fabricate planar field effect transistors (FET) such as high-voltage (HV) devices and/or medium-voltage (MV) devices while the non-planar region 104 could be used to fabricate non-planar devices such as low-voltage (LV) devices or fin field effect transistors (FinFETs) in the later process.

Next, a plurality of fin-shaped structures 14 could be formed on the substrate 12 of the non-planar region 104. According to an embodiment of the present invention, the fin-shaped structures 14 of this embodiment could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 14 could also be obtained by first forming a patterned mask (not shown) on the substrate, 12, and through an etching process, the pattern of the patterned mask is transferred to the substrate 12 to form the fin-shaped structures 14. Moreover, the formation of the fin-shaped structures 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures 14. These approaches for forming fin-shaped structure 14 are all within the scope of the present invention.

Next, a shallow trench isolation (STI) 16 is formed to divide the planar region 102 and non-planar region 104. In this embodiment, the formation of the STI 16 could be accomplished by conducting a flowable chemical vapor deposition (FCVD) process to form a silicon oxide layer in the substrate 12 and around the transistor region 14. Next, a chemical mechanical polishing (CMP) process along with an optional etching process are conducted to remove part of the silicon oxide layer so that the top surface of the remaining silicon oxide is slightly higher than the top surface of the substrate 12 on the planar region 102 for forming the STI 16. Even though the top surface of the STI 16 is slightly higher than the surface of the substrate 12 on the planar region 102 and even with the top surface of the fin-shaped structures 14 on the non-planar region 104, according to other embodiment of the present invention the top surface of the STI 16 could also be even with or slightly higher than the surface of the substrate 12 on the planar region 102, which is also within the scope of the present invention.

Next, gates structures 18, 20 or dummy gates are formed on the substrate 12 of the planar region 102 and non-planar region 104. In this embodiment, the formation of the gate structures 18, 20 could be accomplished by a gate first process, a high-k first approach from gate last process, or a high-k last approach from gate last process. Since this embodiment pertains to a high-k last approach, a gate dielectric layer 24 or interfacial layer, a gate material layer 26 made of polysilicon, and a selective hard mask (not shown) could be formed sequentially on the substrate 12, and a photo-etching process is then conducted by using a patterned resist (not shown) as mask to remove part of the gate material layer 26 through single or multiple etching processes. After stripping the patterned resist, gate structures 18, 20 each composed of a patterned material layer 26 are formed on the substrate 12.

It should be noted that the gate dielectric layer 24 and the gate material layer 26 on the non-planar region 104 could be patterned at the same time to form the gate structure 20. However, according to other embodiment of the present invention, it would also be desirable to only pattern the gate material layer 26 on the non-planar region 104 without patterning the gate dielectric layer 24 so that the gate dielectric layer 24 would cover the entire substrate 12 surface, which is also within the scope of the present invention.

Next, at least a spacer 28 is formed on the sidewalls of the each of the gate structures 18, 20 and source/drain regions 30 and/or epitaxial layers 32 are formed in the substrate 12 adjacent to two sides of the spacer 28. In this embodiment, the spacer 28 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The source/drain regions 30 could include n-type dopants or p-type dopants depending on the type of device being fabricated.

In this embodiment, the epitaxial layers 32 could also be formed to include different materials depending on the type of transistor being fabricated. For instance, if the MOS transistor being fabricated were to be a PMOS transistor, the epitaxial layers 32 could be made of material including but not limited to for example SiGe, SiGeB, or SiGeSn. If the MOS transistor being fabricated were to be a NMOS transistor, the epitaxial layers 32 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 32 are preferred to have less or no germanium atom at all to facilitate the formation of silicide afterwards.

According to an embodiment of the present invention, it would also be desirable to form source/drain regions 30 in part or all of the epitaxial layers 32. According to another embodiment of the present invention, the source/drain regions 30 could also be formed insituly during the SEG process. For instance, the source/drain regions 30 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain regions 30. Moreover, the dopants within the source/drain regions 30 could also be formed with a gradient, which is also within the scope of the present invention.

Next, a contact etch stop layer (CESL) (not shown) could be formed on the gate structures 18, 20 and the STI 16, and an interlayer dielectric (ILD) layer 34 is formed on the gate structures 18, 20. Next, a planarizing process such as CMP is conducted to remove part of the ILD layer 34 and part of the CESL for exposing the gate material layer 26 made of polysilicon so that the top surface of the gate material layer 26 is even with the top surface of the ILD layer 34.

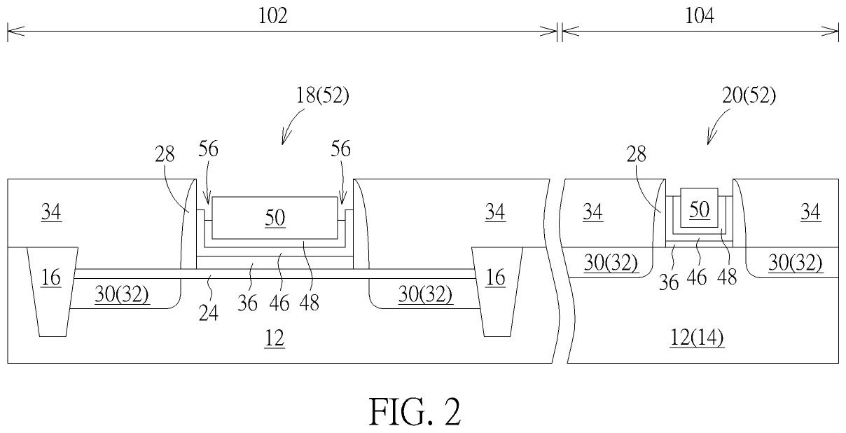

Next, as shown in FIG. 2, a replacement metal gate (RMG) process is conducted to transform the gate structures 18, 20 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layers 26 from each of the gate structures 18, 20 for forming recesses (not shown) in the ILD layer 34.

Next, a selective interfacial layer (not shown) or gate dielectric layer 36, a high-k dielectric layer 46, a work function metal (WFM) layer 48, and a low resistance metal layer 50 are formed in the recesses, and a planarizing process such as CMP is conducted to remove part of low resistance metal layer 50, part of WFM layer 48, and part of high-k dielectric layer 46 to form metal gates 52. In this embodiment, the gate structures or metal gates 52 fabricated through high-k last process of a gate last process preferably includes an interfacial layer or gate dielectric layer 36, a U-shaped high-k dielectric layer 46, a U-shaped WFM layer 48, and a low resistance metal layer 50.

In this embodiment, the gate dielectric layer 24 and the gate dielectric layer 36 could be made of same or different materials such as silicon oxide. The high-k dielectric layer 46 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the WFM layer 48 is formed for tuning the work function of the metal gate in accordance with the conductivity of the device. For an NMOS transistor, the WFM layer 48 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the WFM layer 48 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the WFM layer 48 and the low resistance metal layer 50, in which the material of the barrier layer may include titanium (Ti), titanium nitride (TiN), tantalum (Ta) or tantalum nitride (TaN). Furthermore, the material of the low-resistance metal layer 50 may include copper (Cu), aluminum (Al), titanium aluminum (TiAl), cobalt tungsten phosphide (CoWP) or any combination thereof.

Next, part of the high-k dielectric layer 46, part of the WFM layer 48, and part of the low resistance metal layer 50 are removed to form recesses (not shown). It should be noted that as a result of the selectivity between different materials during etching and removal of part of the high-k dielectric layer 46, part of the WFM layer 48, and part of the low resistance metal layer 50, the top surface of the remaining low resistance metal layer 50 is slightly higher than the top surfaces of the high-k dielectric layer 46 and WFM layer 48.

Specifically, as part of the high-k dielectric layer 46, part of the WFM layer 48, and part of the low resistance metal layer 50 are removed by the etching process, selectivity between these layers 46, 48, 50 is adjusted to remove more high-k dielectric layer 46 and WFM layer 48 and less low resistance metal layer 50 so that at least the top or topmost surface of the remaining WFM layer 48 is lower than the top or topmost surface of the remaining low resistance metal layer 50.

It should be noted that even though part of the high-k dielectric layer 46, part of the WFM layer 48, and part of the low resistance metal layer 50 on both planar region 102 and non-planar region 104 are removed at the same time, as a result of the actual length (such as the distance extending along the X-direction) of the gate structure 18 on the planar region 102 being substantially greater than the length of the gate structure 20 on the non-planar region 104, not only the top surface of the remaining WFM layer 48 on the planar region 102 is lower than the top surface of the low resistance metal layer 50, the top surface of the remaining WFM layer 48 is also lower than the top surface of the remaining high-k dielectric layer 46, and a recess 56 is formed adjacent to one side of the low resistance metal layer 50 while another recess 56 is formed adjacent to another side of the low resistance metal layer 50. Specifically, each of the recesses 56 is formed in the WFM layer 48 or each recess 56 is formed by a sidewall of the high-k dielectric layer 46, a top surface of the WFM layer 48, and a sidewall of the low resistance metal layer 50.

No recess however is formed between the high-k dielectric layer 46 and low resistance metal layer 50 after part of the high-k dielectric layer 46, part of the WFM layer 48, and part of the low resistance metal layer 50 are removed on the non-planar region 104, hence the top surface of the remaining WFM layer 48 is lower than the top surface of the low resistance metal layer 50 and the top surfaces of remaining WFM layer 48 and high-k dielectric layer 46 are coplanar on the non-planar region 104.

Preferably, etching gases including chlorine gas (Cl₂) and/or boron trichloride (BCl₃) could be used without any patterned mask to remove part of the high-k dielectric layer 46, part of the WFM layer 48, and part of the low resistance metal layer 50 on the planar region 102 while no spacer 28 is consumed. This recipe preferably removes most WFM layer 48, less high-k dielectric layer 46 and least function metal layer 50 on the planar region 102 so that three different heights are formed, in which the top surface of the remaining WFM layer 48 is slightly lower than the top surface of the remaining high-k dielectric layer 46 while the top surface of the remaining high-k dielectric layer 46 is lower than the top surface of the remaining low resistance metal layer 50.

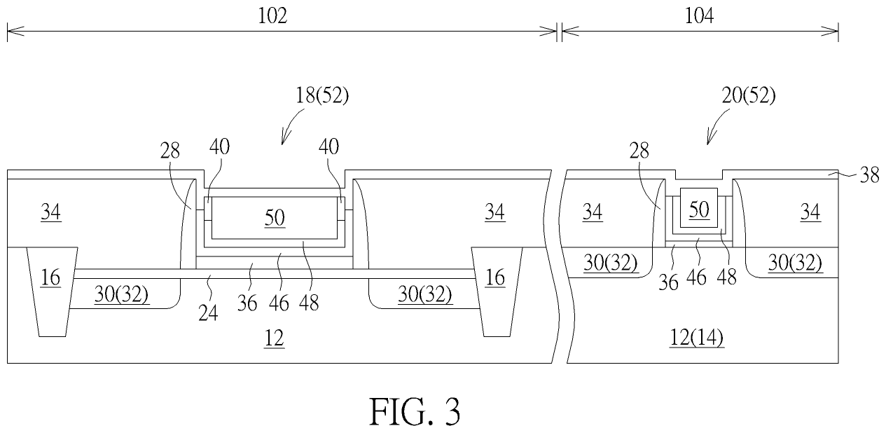

Next, as shown in FIG. 3, a buffer layer 38 is formed to seal the recesses 56 adjacent to two sides of the low resistance metal layer 50 for forming an air gap 40 or void on one side such as left of the low resistance metal layer 50 and another air gap 40 on another side such as right side of the low resistance metal layer 50. It should be noted that since a height difference is found between the high-k dielectric layer 46 and WFM layer 48 on the planar region 102 while no height difference is found between the high-k dielectric layer 46 and WFM layer 48 on the non-planar region 104, the air gaps 40 would only be formed on the original recesses 56 location of the planar region 102 after the buffer layer 38 is deposited on the gate structures 18, 20 and ILD layer 34 on both the planar region 102 and non-planar region 104 as the buffer layer 38 on the non-planar region 104 would be formed to directly contacting the surfaces of the high-k dielectric layer 46 and WFM layer 48. In this embodiment, the buffer layer 38 preferably includes silicon nitride and the thickness of the buffer layer 38 is between 90-110 Angstroms or most preferably at 100 Angstroms.

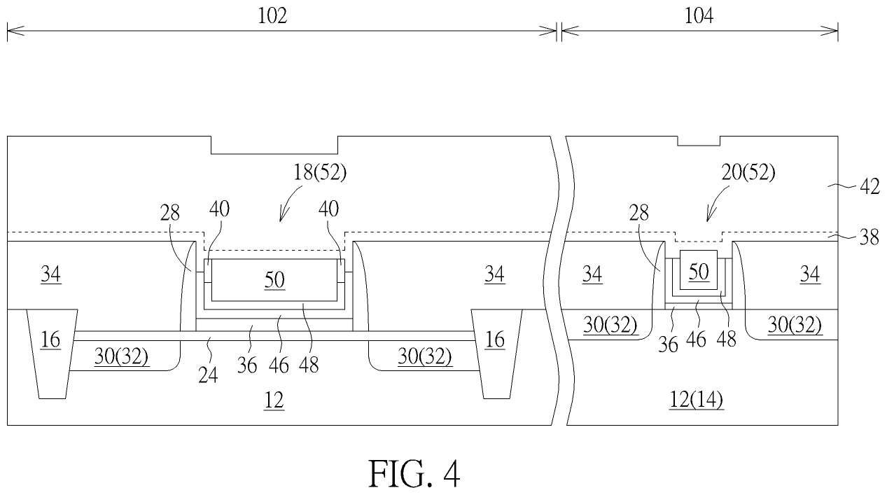

Next, as shown in FIG. 4, a hard mask 42 is formed on the buffer layer 38 on both planar region 102 and non-planar region 104. In this embodiment, the hard mask 42 and the buffer layer 38 could include same or different materials, in which the hard mask 42 preferably includes silicon nitride and the thickness of the hard mask 42 is between 800-1000 Angstroms or most preferably 920 Angstroms. According to other embodiment of the present invention, the hard mask 42 could also include SiO₂, SiN, SiON, SiCN, or combination thereof.

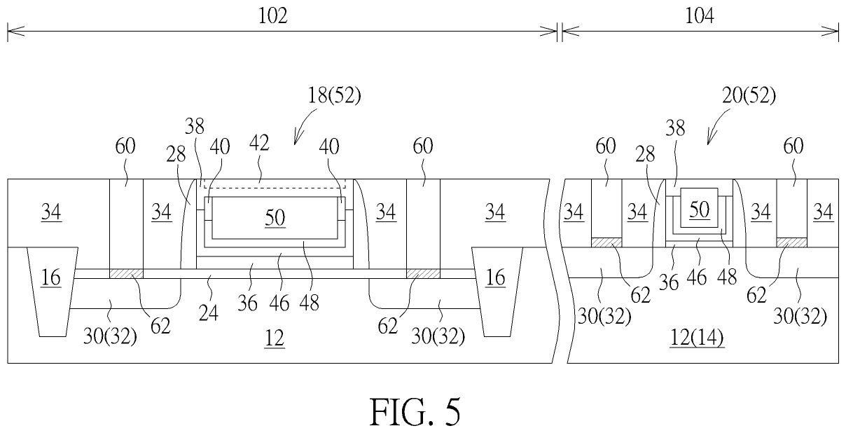

Next, as shown in FIG. 5, a planarizing process such as CMP is conducted to remove part of the hard mask 42 so that the top surface of the hard mask 42 is even with the top surface of the ILD layer 34. It should be noted that due to smaller scale of the gate structure 20 on the non-planar region 104, only buffer layer 38 is remained on the metal gate 52 after the planarizing process. Nevertheless, according to other embodiment of the present invention, both buffer layer 38 and hard mask 42 could be remained on both the planar region 102 and the non-planar region 104 as top the top surfaces of the buffer layer 38, hard mask 42, and ILD layer 34 are coplanar, which is also within the scope of the present invention.

Next, a contact plug formation process is conducted to form contact plugs 60 connecting the source/drain regions 30 adjacent to the gate structures 18, 20. In this embodiment, the formation of the contact plugs 60 could be accomplished by first removing part of the ILD layer 34 to form contact holes (not shown) and then depositing a barrier layer (not shown) and a metal layer (not shown) on the substrate 12 to fill the contact holes. Next, a planarizing process such as CMP is conducted to remove part of the metal layer, part of the barrier layer, and even part of the ILD layer 34 to form contact plugs 60 in the contact holes as the top surface of the contact plugs 60 is even with the top surface of the ILD layer 34. In this embodiment, the ILD layer 34 could include silicon oxide, the barrier layer is selected from the group consisting of Ti, Ta, TiN, TaN, and WN, and the metal layer is selected from the group consisting of Al, Ti, Ta, W, Nb, Mo, and Cu.

It should be noted that a salicide process could be conducted after the aforementioned barrier layer and metal layer are deposited in the contact holes. Preferably, the salicide process could be accomplished by conducting an anneal process after the barrier layer and metal layer are formed so that part of the barrier layer is reacted with the substrate 12 to form silicides 62 between the substrate 12 and the contact plugs 60. Next, a back end of line (BEOL) process such as a metal interconnective process could be conducted by first forming an inter-metal dielectric (IMD) layer (not shown) on the ILD layer 34, performing a photo-etching process to remove part of the IMD layer for forming contact holes (not shown) exposing the contact plug 60, depositing metal or conductive material into the contact holes along with a planarizing process to form metal interconnections made of via conductors and trench conductors, and then forming a stop layer on the metal interconnections. In this embodiment, the IMD layer preferably includes silicon oxide or dielectric material having dielectric constant between 2.4-3.6 such as porous dielectric material including but not limited to for example silicon oxycarbide (SiOC) or carbon doped silicon oxide (SiOCH), the metal interconnections preferably include copper, and the stop layer preferably includes nitrogen doped carbide (NDC), silicon nitride, silicon carbon nitride (SiCN), or combination thereof. This completes the fabrication of a semiconductor device according to an embodiment of the present invention.

Referring again to FIG. 5, FIG. 5 further illustrates a structural view of a semiconductor device according to an embodiment of the present invention. As shown in FIG. 5, the semiconductor device on the planar region 102 includes a metal gate 52 disposed on the substrate 12, a spacer 28 around the metal gate 52, an ILD layer 34 around the metal gate 52, an air gap 40 adjacent to one side such as left side of the metal gate 52 and between the spacer 28 and the metal gate 52, another air gap 40 adjacent to another side such as right side of the metal gate 52 and between the spacer 28 and the metal gate 52, a buffer layer 38 disposed on the air gaps 40 and the metal gate 52, and a hard mask 42 disposed on the buffer layer 38. Preferably, the metal gate 52 includes a high-k dielectric layer 46 disposed on the substrate 12, a WFM layer 48 disposed on the high-k dielectric layer 46, and a low resistance metal layer 50 disposed on the WFM layer 48.

Viewing from a more detailed perspective, the top or topmost surface of the WFM layer 48 is lower than the top surface of the high-k dielectric layer 46 and the top surface of the low resistance metal layer 50 while the top surface of the high-k dielectric layer 46 is also lower than the top surface of the low resistance metal layer 50, each air gap 40 is disposed between the high-k dielectric layer 46 and the low resistance metal layer 50 or more specifically surrounded by the high-k dielectric layer 46, the WFM layer 48, the low resistance metal layer 50, and the buffer layer 38. It should be noted that even though the top surface of each air gap 40 is substantially even with the top surface of the low resistance metal layer 50 in the aforementioned embodiment, according to other embodiment of the present invention, the top surface of each air gap 40 could also be slightly higher than or lower than the top surface of the low resistance metal layer 50 or even lower than the top or topmost surface of the high-k dielectric layer 46, which are all within the scope of the present invention.

Overall, the present invention provides a semiconductor device including both planar and non-planar transistors applied in DDICs, in which the fabrication of the semiconductor device first forms a metal gate on a substrate and an ILD layer around the metal gate and then removes part of the high-k dielectric layer, part of the WFM layer, and part of the low resistance metal layer in the metal gate by using selectivity between the layers so that a height difference is created among the remaining high-k dielectric layer, WFM layer, and low resistance metal layer and at the same time recesses 56 are formed adjacent to two sides of the low resistance metal layer. A buffer layer is then formed on the metal layer afterwards to seal the recesses for forming air gaps. According to a preferred embodiment of the present invention, the formation of the air gap within the metal gate on the planar region facilitates lowering of gate-source capacitance (Cgs) and gate-drain capacitance (Cgd) thereby improving overall slew rate of DDICs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
forming a metal gate on a substrate and an interlayer dielectric (ILD) layer around the metal gate;
removing part of the metal gate to form a first recess; and
forming a buffer layer on the metal gate to seal the first recess for forming a first air gap.

2. The method of claim 1, further comprising:
forming a gate structure on a substrate;
forming the ILD layer around the gate structure;
transforming the gate structure into the metal gate, wherein the metal gate comprises a high-k dielectric layer, a work function metal (WFM) layer, and a low resistance metal layer;
removing the low resistance metal layer, the WFM layer, and the high-k dielectric layer to form the first recess adjacent to one side of the low resistance metal layer and a second recess adjacent to another side of the low resistance metal layer;
forming the buffer layer to seal the first recess and the second recess for forming the first air gap and a second air gap; and
forming a hard mask on the buffer layer.

3. The method of claim 2, wherein a top surface of the WFM layer is lower than a top surface of the high-k dielectric layer.

4. The method of claim 2, wherein a top surface of the WFM layer is lower than a top surface of the low resistance metal layer.

5. The method of claim 2, wherein a top surface of the high-k dielectric layer is lower than a top surface of the low resistance metal layer.

6. The method of claim 2, wherein the first air gap is between the high-k dielectric layer and the low resistance metal layer.

7. The method of claim 2, wherein the second air gap is between the high-k dielectric layer and the low resistance metal layer.

8. A semiconductor device, comprising:
a metal gate on a substrate;
a spacer adjacent to the metal gate;
an interlayer dielectric (ILD) layer around the metal gate; and
a first air gap adjacent to one side of the metal gate and between the spacer and the metal gate.

9. The semiconductor device of claim 8, further comprising:
a second air gap adjacent to another side of the metal gate and between the spacer and the metal gate.

10. The semiconductor device of claim 9, wherein the metal gate comprises:
a high-k dielectric layer on the substrate;
a work function metal (WFM) layer on the high-k dielectric layer; and
a low resistance metal layer on the WFM layer.

11. The semiconductor device of claim 10, wherein a top surface of the WFM layer is lower than a top surface of the high-k dielectric layer.

12. The semiconductor device of claim 10, wherein a top surface of the WFM layer is lower than a top surface of the low resistance metal layer.

13. The semiconductor device of claim 10, wherein a top surface of the high-k dielectric layer is lower than a top surface of the low resistance metal layer.

14. The semiconductor device of claim 10, further comprising:
a buffer layer on the first air gap, the low resistance metal layer, and the second air gap; and
a hard mask on the buffer layer.

15. The semiconductor device of claim 10, wherein the first air gap is between the high-k dielectric layer and the low resistance metal layer.

16. The semiconductor device of claim 10, wherein the second air gap is between the high-k dielectric layer and the low resistance metal layer.
